(19) United States
(12) Patent Application Publication
(10) Pub. No.: US 2026/0317945 A1
(43) Pub. Date: Oct. 15, 2026

(54) METHOD FOR PRODUCING GROUP III NITRIDE SEMICONDUCTOR

(71) Applicant: TOYODA GOSEI CO., LTD., Kiyosu-shi (JP)

(72) Inventors: Haruka HACHIKAWA, Kiyosu-shi (JP); Taku FUJIMORI, Kiyosu-shi (JP); Miki MORIYAMA, Kiyosu-shi (JP)

(21) Appl. No.: 19/641,462

(22) Filed: Apr. 7, 2026

(30) Foreign Application Priority Data
Apr. 9, 2025 (JP) 2025-064571

(51) Int. Cl. C30B 25/02

(52) U.S. Cl. CPC C30B 25/02

(57) ABSTRACT

A method for producing a Group III nitride semiconductor includes: holding, in a crucible, a melt in which a Group III metal is dissolved in a flux; and supplying a nitrogen-containing gas to the melt to grow a Group III nitride semiconductor, and the crucible contains alumina as a main component and contains a P-type dopant.

### CROSS-REFERENCE TO RELATED APPLICATION

This application is based on and claims priority under 35 USC 119 from Japanese Patent Application No. 2025-064571 filed on Apr. 9, 2025.

### TECHNICAL FIELD

The present invention relates to a method for producing a Group III nitride semiconductor.

### BACKGROUND ART

As a method for growing a GaN crystal, a method called a Na flux method is known. This is a technique in which a nitrogen gas is introduced into a mixed melt of Na (sodium) and Ga (gallium), and GaN can be grown at a relatively low pressure of several MPa and at a relatively low temperature of 600°C to 1000°C.

On the other hand, in a power device in which a large current flows, a high-resistance semiconductor is required. As a method of increasing the resistance of the GaN crystal, for example, Patent Literature 1 discloses a method of adding a small amount of Mg to a mixed melt of Na and Ga in a Na flux method. According to this method, since Mg functions as a P-type dopant, a high-resistance GaN crystal can be obtained.

Patent Literature 1: WO 2005/064661

### SUMMARY OF INVENTION

However, in a configuration disclosed in Patent Literature 1, Mg is weighed and added to the melt in the crucible, but since the amount of Mg to be added is small, it is difficult to accurately weigh Mg, and an excessive amount of Mg may be added. When an excessive amount of Mg is added, a growth rate of the GaN crystal decreases, generation of miscellaneous crystals is promoted, and uniformity of an in-plane distribution of Mg in a GaN crystal substrate decreases, resulting in a decrease in crystal quality of the GaN crystal. This similarly applies not only to the GaN crystal but also to other Group III nitride semiconductors. Therefore, there is room for improvement in obtaining a Group III nitride semiconductor having an excellent crystal quality and high resistance.

The present invention has been made in view of such a circumstance, and an object thereof is to provide a method for producing a Group III nitride semiconductor capable of obtaining a Group III nitride semiconductor having an excellent crystal quality and high resistance.

One aspect of the present invention provides a method for producing a Group III nitride semiconductor, including:
holding, in a crucible, a melt in which a Group III metal is dissolved in a flux; and
supplying a nitrogen-containing gas to the melt to grow a Group III nitride semiconductor, in which
the crucible contains alumina as a main component and contains a P-type dopant.

In the method for producing a Group III nitride semiconductor according to the above aspect, a melt in which a Group III metal is dissolved in a flux is held in a crucible containing alumina as a main component and contains a P-type dopant, whereby an extremely small amount of the P-type dopant is dissolved into the melt. Accordingly, an excessive amount of the P-type dopant is prevented from being added to the melt, so that a Group III nitride semiconductor having excellent crystallinity and high resistance can be obtained.

As described above, according to the above aspect, it is possible to provide a method for producing a Group III nitride semiconductor capable of obtaining a Group III nitride semiconductor having an excellent crystal quality and high resistance.

### BRIEF DESCRIPTION OF DRAWINGS

FIG. 1 is a conceptual diagram showing a configuration of a crystal growth apparatus in a first embodiment.

FIG. 2 is a figure in which (a) of FIG. 2 shows a photograph of a GaN crystal prepared in a crucible containing no Mg, and (b) of FIG. 2 shows a GaN crystal prepared in a crucible containing Mg.

FIG. 3 shows results of a check test 1 in the first embodiment.

FIG. 4 shows results of a first measurement test in the first embodiment.

FIG. 5 shows results of a second measurement test in the first embodiment.

### DESCRIPTION OF EMBODIMENTS

The P-type dopant preferably contains at least one of Mg or Zn. In this case, since Mg and Zn effectively act as the P-type dopant, the resistance of the Group III nitride semiconductor can be sufficiently increased.

Preferably, the crucible contains at least one of MgO or MgCO₃, and the P-type dopant is Mg derived from the at least one of MgO or MgCO₃ contained in the crucible. In this case, MgCO₃ or MgO is easy to handle and easily available, and Mg serving as the P-type dopant is easily dispersed in the crucible containing alumina as a main component, so that Mg is easily gradually released into the melt melted in the crucible. Therefore, a Group III nitride semiconductor having an excellent crystal quality and high resistance can be produced at a low cost.

A concentration of the MgO in the crucible is preferably 2 mol% or more. In this case, a Group III nitride semiconductor having sufficiently high resistance can be produced.

A concentration of the MgCO₃ in the crucible is preferably 1 mol% or more. In this case, a Group III nitride semiconductor having sufficiently high resistance can be produced.

The Group III nitride semiconductor preferably has a resistivity of 1.00 × 10⁷ Ω·cm or more. In this case, the Group III nitride semiconductor is suitable for applications requiring high resistance, such as a power device.

A concentration of the P-type dopant in the melt is preferably 0.1 mol% or more. In this case, a Group III nitride semiconductor having sufficiently high resistance can be produced.

A concentration of the P-type dopant in the Group III nitride semiconductor is preferably 10⁸ cm⁻³ or more. In this case, a Group III nitride semiconductor having sufficiently high resistance can be produced.

A concentration of the Ca in the melt is preferably less than 0.01 mol%. Since promotion of crystal growth is ensured by the P-type dopant, it is not necessary to add Ca for promoting the crystal growth, and generation of miscellaneous crystals due to the addition of Ca is prevented, so that the crystal quality of the Group III nitride semiconductor can be improved.

### FIRST EMBODIMENT

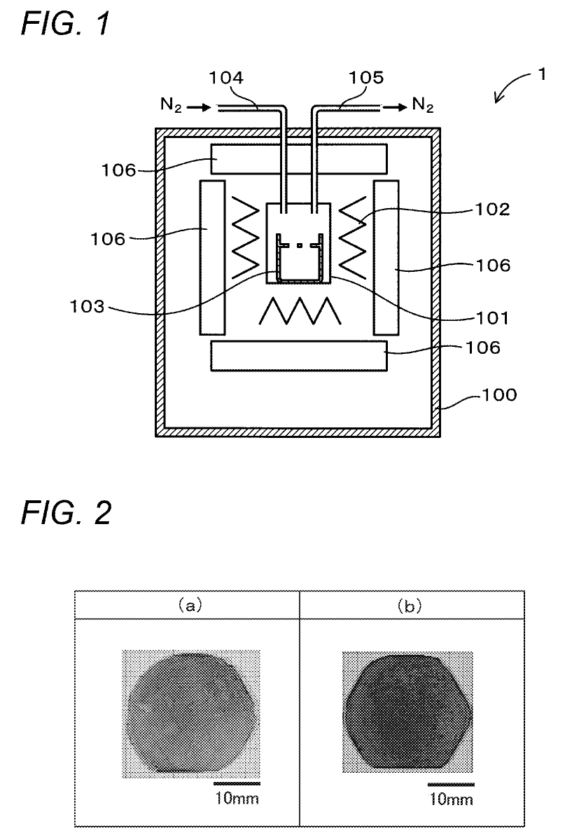

First, a configuration of a crystal growth apparatus 1 used in a method for producing a Group III nitride semiconductor according to a first embodiment will be described with reference to FIG. 1.

### 1. Configuration of Crystal Growth Apparatus 1

As shown in FIG. 1, the crystal growth apparatus 1 includes a pressure vessel 100, and a reaction vessel 101 and a heater 102 inside the pressure vessel 100. A crucible 103 is disposed inside the reaction vessel 101. In addition, a supply pipe 104 for supplying a nitrogen gas into the reaction vessel 101 and an exhaust pipe 105 for exhausting the nitrogen gas are provided. In addition, a heat insulating material 106 is provided inside the pressure vessel 100 so as to surround the reaction vessel 101 and the heater 102.

The pressure vessel 100 is made of stainless steel and has pressure resistance. The reaction vessel 101 is made of SUS and has heat resistance. The heater 102 heats the reaction vessel 101 by resistance heating, thereby adjusting a growth temperature. In addition, the supply pipe 104 and the exhaust pipe 105 connected to the reaction vessel 101 are provided with valves, and by adjusting a supply amount and an exhaust amount of the nitrogen gas by the valves, a pressure in the reaction vessel 101 is adjusted and a growth pressure is adjusted.

### 2. Configuration of Crucible 103

The crucible 103 is a vessel for holding a seed crystal (GaN free-standing substrate), Na as a flux, Ga as a raw material, and other impurities. The crucible 103 contains alumina as a main component and contains a P-type dopant. The P-type dopant increases the resistance of GaN, and examples thereof include Mg, Zn, Be, Sr, Fe, and Mn, among which Mg or Zn is preferably used. The crucible 103 contains alumina as a main component, and thus has high heat resistance and alkali resistance.

At least one of MgO or MgCO₃ is contained in the crucible 103, and Mg derived from the at least one of MgO or MgCO₃ can be used as the P-type dopant. In the case where the crucible 103 contains MgO, a concentration of MgO is not limited, and is preferably 2 mol% or more. In the case where the crucible 103 contains MgCO₃, a concentration of MgCO₃ is not limited, and is preferably 1 mol% or more. In either case, Mg can be released into a melt as a P-type dopant necessary for imparting high resistance.

A shape of the crucible 103 is not limited, and in the present embodiment, the crucible 103 has a cylindrical shape. A size of crucible 103 is not limited and can be set as appropriate. The crucible 103 installed in the reaction vessel 101 is rotatable by a device (not shown). The crucible 103 may be provided with a lid. It is possible to suppress evaporation of Na during growth of a GaN crystal.

A method of forming the crucible 103 is not limited, and the crucible 103 can be prepared by casting using a gypsum mold, for example. Specifically, it is prepared as follows. First, as raw materials, an alumina powder, a MgO or MgCO₃ powder, and water are mixed to prepare a slurry (suspension), which is poured into a gypsum mold made of gypsum. A wet jet mill treatment or the like is used to prepare the slurry. Then, the gypsum mold is allowed to stand for a predetermined time to absorb moisture, and the alumina powder having a constant thickness is deposited on a surface of the gypsum mold. Next, the liquid slurry remaining in the gypsum mold is discarded, and only a layer of the alumina powder and the MgO or MgCO₃ powder deposited on the surface of the gypsum mold remains. The remaining layer of the alumina powder and the MgO or MgCO₃ powder is dried for a predetermined time, and the deposited layer is solidified to obtain a molded body. Then, the molded body is taken out of the gypsum mold, and the molded body is sintered in the air at 1570°C to produce the crucible 103, which is a sintered body of alumina containing the MgO or MgCO₃ powder.

Various conditions in the casting may be as follows. An average particle diameter of the alumina powder used for preparing the slurry is preferably 0.1 μm to 1 μm. The alumina particles in the crucible 103 are denser, and a strength can be improved.

Although water is used as a solvent for the slurry, any solvent known used as a solvent for a slurry, such as an alcohol, a ketone, or an amine, may be used. However, it is preferable to use water from the viewpoint of absorption of the solvent into the mold, an environmental load, and absence of the solvent remaining in the crucible 103. The water is preferably distilled water from the viewpoint of preventing contamination with impurities.

In addition, although the gypsum mold is used as the mold, a mold made of any material can be used as long as the mold can absorb the solvent for the slurry and mix impurities into the slurry. Alternatively, in the case of using a mold made of a material in which impurities are not much melted in the slurry, the impurities may be added to the slurry to artificially cause abnormal grain growth. However, it is desirable to use a gypsum mold as the mold for casting. This is because it is inexpensive and it is easy to mix impurities into the slurry.

A sintering temperature for the molded body is desirably 1500°C to 1600°C. This is to make the alumina particles dense and prevent the alumina particles from being too large.

In addition, a sintering aid for promoting the sintering, a dispersant for uniformly dispersing the alumina powder in the solvent, and the like may be added to the slurry. In the case of adding a dispersant, a heat treatment for removing the dispersant from the molded body may be performed at a temperature lower than the temperature at which the molded body is sintered, before sintering the molded body.

### 3. Method for Producing Group III Nitride Semiconductor

Next, a method for producing a Group III nitride semiconductor using the crystal growth apparatus 1 shown in FIG. 1 will be described. The method for producing a Group III nitride semiconductor according to the present embodiment is a method for growing a Group III nitride single crystal by using a flux method. Accordingly, a Group III nitride semiconductor is produced. The flux method is a method for epitaxially growing a Group III nitride semiconductor in a liquid phase by supplying a nitrogen-containing gas to a melt containing an alkali metal to be a flux and a Group III metal as a raw material to dissolve the gas therein.

In the present embodiment, the melt contains Na as an alkali metal to be a flux. The Group III metal as a raw material is at least one of gallium (Ga), aluminum (Al), or indium (In), and a composition of the Group III nitride single crystal to be formed can be controlled based on a ratio thereof. GaN, AlN, InN, AlGaN, InGaN, AlGaInN, and the like can be formed. The present invention is particularly suitable for formation of GaN, and in the first embodiment, a semiconductor made of a GaN single crystal is produced. In addition, Na is used as the flux, and such a flux method is particularly referred to as a Na flux method. The nitrogen-containing gas is nitrogen molecules or a compound gas containing nitrogen as a constituent element, such as ammonia, and may be a mixed gas thereof, or the nitrogen-containing gas may be mixed with an inert gas such as a rare gas.

In the method for producing a Group III nitride semiconductor according to the present embodiment, first, a GaN free-standing substrate prepared by using an ammonothermal method is disposed as a seed crystal in the crucible 103, and predetermined amounts of Ga, Na, and C are further charged thereto. C is added for the purpose of suppressing the miscellaneous crystals and improving the crystallinity, as well as for the purpose of allowing the grown GaN crystal to efficiently incorporate the dopant. C acts catalytically and is hardly incorporated into the GaN crystal to be grown, and a concentration of C in the crystal is 1 × 10¹⁶/cm³ or less.

The crucible 103 contains MgO or MgCO₃. An operation of setting the material in the crucible 103 is performed in a glove box filled with an inert gas such as Ar. This is to prevent impurities from being mixed due to oxidation of Na or the like.

The seed crystal is not limited to the GaN free-standing substrate, and a template substrate may be used. The template substrate is obtained by growing GaN on a substrate different from the Group III nitride semiconductor such as sapphire by using an MOCVD method, an HVPE method, an MBE method, or the like. In the case of using the GaN free-standing substrate, a thickness thereof is preferably 500 μm or more such that the GaN free-standing substrate does not melt back or disappear at the initial stage of growth. Alternatively, an AlGaN layer may be formed on a surface of the GaN free-standing substrate to prevent the melting back.

Next, the crucible 103 is heated to 845°C by the heater 102, a nitrogen gas is introduced into the reaction vessel 101 via the supply pipe 104, and the pressure in the reaction vessel 101 is set to 3 MPa by adjusting the valves of the supply pipe 104 and the exhaust pipe 105. Accordingly, a melt in which Na, Ga, C, and Ge charged and Mg eluted from the crucible 103 are mixed is generated in the crucible 103. Then, when nitrogen is dissolved into the melt and nitrogen in the melt is supersaturated, a Mg-doped p-GaN crystal starts to grow on the seed crystal. This state is maintained for a predetermined time, and the Mg-doped p-GaN crystal is grown on the seed crystal. During the growth, the crucible 103 is rotated, and a rotation direction is reversed at predetermined intervals. Accordingly, the melt in the crucible 103 is stirred. This is to homogenize the melt and improve the crystal quality of the grown p-GaN crystal. In addition to nitrogen, a gas containing N as a constituent element can be used as the gas introduced into the reaction vessel 101, and for example, ammonia may be used.

The temperature and the pressure during the growth are not limited to the above values, and the temperature may be 600°C to 1000°C. The temperature is more desirably 800°C to 950°C, and still more desirably 850°C to 900°C. The pressure may be 1 MPa to 6 MPa, more desirably 2 MPa to 5 MPa, and still more desirably 2.5 MPa to 4 MPa.

Thereafter, the heating by the heater 102 is stopped, and the supply of the nitrogen gas via the supply pipe 104 is stopped to return to a normal temperature and a normal pressure. Then, the p-GaN crystal grown on the GaN free-standing substrate is taken out from the crucible 103, and Na adhering to the p-GaN crystal is removed using ethanol. Accordingly, a GaN semiconductor is prepared.

(a) of FIG. 2 shows, as a comparative example, a crystal photograph prepared by using a method for producing a Group III nitride semiconductor using the crucible 103 containing no MgO or MgCO₃ in a conventional method, and (b) of FIG. 2 shows, as a test example, a crystal photograph prepared by using a method for producing a Group III nitride semiconductor using the crucible 103 containing 5 mol% of MgO in the first embodiment.

### 4. Amount of P-type Dopant Incorporated into Group III Nitride Semiconductor

Next, there was performed a check test regarding an amount of the P-type dopant incorporated into the Group III nitride semiconductor prepared by using the method for producing a Group III nitride semiconductor according to the first embodiment. The test conditions were as follows: a GaN semiconductor was prepared by using the method for producing a Group III nitride semiconductor using crucibles 103 containing MgO and having different MgO concentrations, and using a SIMS (secondary ion mass spectrometry) apparatus (model number: IMS6F, manufactured by CAMECA), the amount of Mg incorporated into the GaN crystal was measured as the amount of Mg incorporated.

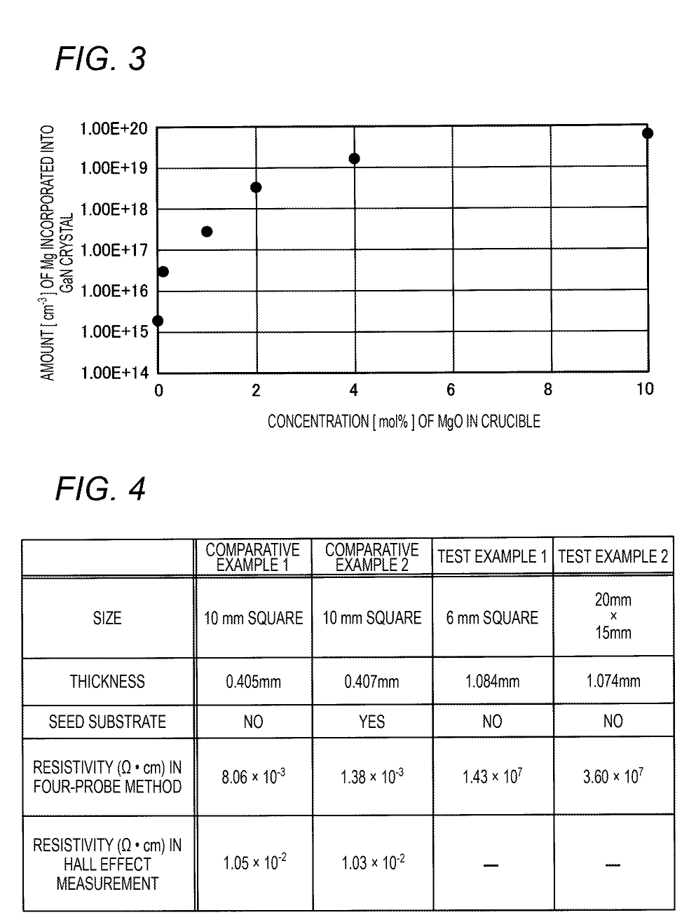

As shown in a graph in FIG. 3 showing a relationship between the concentration of MgO in the crucible 103 and the amount of Mg incorporated, the concentration of MgO in the crucible 103 and the amount of Mg incorporated have a positive correlation. When the concentration of MgO in the crucible 103 is about 5 mol%, it is found that the amount of Mg incorporated is 1 × 10¹⁹ cm⁻³ or more.

### 5. Measurement of Resistivity of Group III Nitride Semiconductor

Next, first measurement and second measurement regarding a resistivity of the Group III nitride semiconductor prepared by using the method for producing a Group III nitride semiconductor according to the first embodiment were performed.

First, in the first measurement test, as a test example, Test Examples 1 and 2, i.e., the Group III nitride semiconductor prepared by using the method for producing a Group III nitride semiconductor using the crucible 103 containing 5 mol% of MgCO₃ in the first embodiment described above were prepared. Test Example 1 had a size of 6 mm square and a thickness of 1.084 mm, and Test Example 2 had a size of 20 mm × 15 mm and a thickness of 1.074 mm. In addition, Comparative Examples 1 and 2, i.e., a Group III nitride semiconductor prepared by using the above method for producing a Group III nitride semiconductor using the crucible 103 containing no dopant were prepared. Comparative Example 1 had a size of 10 mm square and a thickness of 0.405 mm, and Comparative Example 2 had a size of 10 mm square and a thickness of 0.415 mm (including the substrate). In Comparative Examples 1 and 2, Ca was contained in the melt at a predetermined concentration.

In the first measurement test, the resistivity of each of Test Examples 1 and 2 and Comparative Examples 1 and 2 was measured based on a four-probe method inspection method using a four-probe method inspection apparatus (model number MCP-T600, manufactured by Nittoseiko Analytech Co., Ltd.). In addition, in Comparative Examples 1 and 2, the resistivity was measured by performing Hall effect measurement based on the Van der Pauw method using a Hall effect measurement apparatus (model number Resi Test 8403, manufactured by TOYO Corporation).

The measurement results of the resistivity in the first measurement test are shown in FIG. 4. As shown in FIG. 4, in Comparative Examples 1 and 2, the resistivity was about 10⁻³Ω·cm to 10⁻² Ω·cm, but in Test Examples 1 and 2, the resistivity was as high as 10⁷ Ω·cm or more.

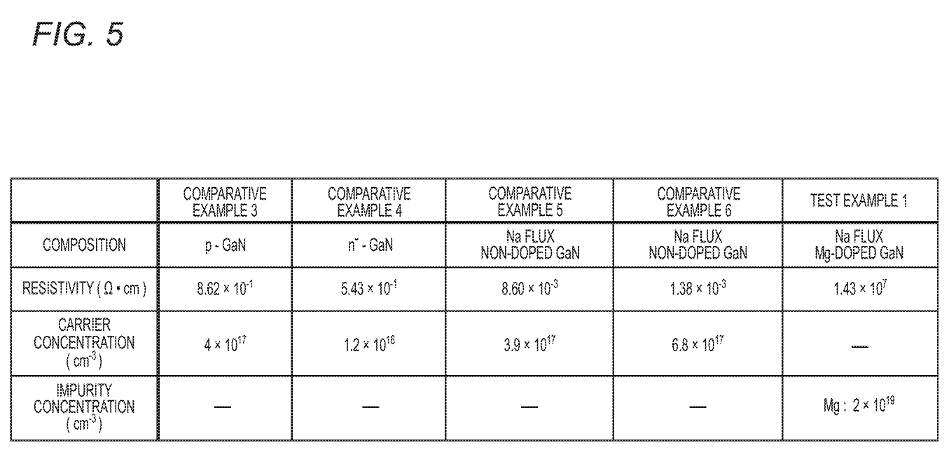

Next, in the second measurement test, the resistivity of each of Comparative Examples 3 to 6 and Test Example 1 of the semiconductor having each composition shown in FIG. 5 was measured. As shown in FIG. 5, according to the second measurement test, the resistivity of Test Example 1 was significantly higher than that of Comparative Examples 3 to 6.

### 6. Operations and Effects

With the method for producing a Group III nitride semiconductor according to the first embodiment, the melt in which a Group III metal is dissolved in a flux is held in the crucible 103 containing alumina as a main component and contains a P-type dopant, whereby an extremely small amount of the P-type dopant is dissolved into the melt. Accordingly, an excessive amount of the P-type dopant is prevented from being added to the melt, so that a Group III nitride semiconductor having excellent crystallinity and high resistance can be obtained.

In the first embodiment, the P-type dopant contains at least one of Mg or Zn. Since Mg and Zn effectively act as the P-type dopant, the resistance of the Group III nitride semiconductor can be sufficiently increased.

In the first embodiment, the crucible 103 contains at least one of MgO or MgCO₃, and the P-type dopant is Mg derived from the at least one of MgO or MgCO₃ contained in the crucible 103. MgCO₃ and MgO are easy to handle and easily available, and Mg serving as the P-type dopant is easily dispersed in the crucible 103 containing alumina as a main component, so that Mg is easily gradually released into the melt melted in the crucible 103. Therefore, a Group III nitride semiconductor having an excellent crystal quality and high resistance can be produced at a low cost.

In the first embodiment, the concentration of MgO in the crucible 103 is 2 mol% or more. Accordingly, a Group III nitride semiconductor having sufficiently high resistance can be produced.

Instead of the case of the first embodiment, the concentration of MgCO₃ in the crucible 103 can be 1 mol% or more. In this case, a Group III nitride semiconductor having sufficiently high resistance can also be produced.

In the first embodiment, the Group III nitride semiconductor has a resistivity of 1.00 × 10⁷Ω·cm or more. Accordingly, the Group III nitride semiconductor is suitable for applications requiring high resistance, such as a power device.

In the first embodiment, the concentration of the P-type dopant in the melt is 0.1 mol% or more. Accordingly, a Group III nitride semiconductor having sufficiently high resistance can be produced.

In the first embodiment, the concentration of the P-type dopant in the Group III nitride semiconductor is 10⁸ cm⁻³ or more. Accordingly, a Group III nitride semiconductor having sufficiently high resistance can be produced.

In the first embodiment, the concentration of Ca in the melt is less than 0.01 mol%. Since the promotion of the crystal growth is ensured by the P-type dopant, it is not necessary to add Ca for promoting the crystal growth, and the generation of miscellaneous crystals due to the addition of Ca is prevented, so that the crystal quality of the Group III nitride semiconductor can be improved.

As described above, according to the above aspect, it is possible to provide a method for producing a Group III nitride semiconductor capable of obtaining a Group III nitride semiconductor having an excellent crystal quality and high resistance.

The present invention is not limited to the above embodiment and modification, and may be applied to various embodiments without departing from the gist of the present invention.

### REFERENCE SIGNS LIST

1: crystal growth apparatus

100: pressure vessel

101: reaction vessel

102: heater

103: crucible

104: supply pipe

105: exhaust pipe

What is claimed is:

1. A method for producing a Group III nitride semiconductor, comprising:
holding, in a crucible, a melt in which a Group III metal is dissolved in a flux; and
supplying a nitrogen-containing gas to the melt to grow a Group III nitride semiconductor, wherein
the crucible contains alumina as a main component and contains a P-type dopant.

2. The method for producing a Group III nitride semiconductor according to claim 1, wherein the P-type dopant contains at least one of Mg or Zn.

3. The method for producing a Group III nitride semiconductor according to claim 1, wherein
the crucible contains at least one of MgO or MgCO₃ and
the P-type dopant is Mg derived from the at least one of MgO or MgCO₃ contained in the crucible.

4. The method for producing a Group III nitride semiconductor according to claim 3, wherein a concentration of the MgO in the crucible is 2 mol% or more.

5. The method for producing a Group III nitride semiconductor according to claim 3, wherein a concentration of the MgCO₃ in the crucible is 1 mol% or more.

6. The method for producing a Group III nitride semiconductor according to claim 1, wherein the Group III nitride semiconductor has a resistivity of 1.00 × 10⁷ Ω·cm or more.

7. The method for producing a Group III nitride semiconductor according to claim 2, wherein the Group III nitride semiconductor has a resistivity of 1.00 × 10⁷ Ω·cm or more.

8. The method for producing a Group III nitride semiconductor according to claim 3, wherein the Group III nitride semiconductor has a resistivity of 1.00 × 10⁷ Ω·cm or more.

9. The method for producing a Group III nitride semiconductor according to claim 4, wherein the Group III nitride semiconductor has a resistivity of 1.00 × 10⁷ Ω·cm or more.

10. The method for producing a Group III nitride semiconductor according to claim 1, wherein a concentration of the P-type dopant in the melt is 0.1 mol% or more.

11. The method for producing a Group III nitride semiconductor according to claim 2, wherein a concentration of the P-type dopant in the melt is 0.1 mol% or more.

12. The method for producing a Group III nitride semiconductor according to claim 3, wherein a concentration of the P-type dopant in the melt is 0.1 mol% or more.

13. The method for producing a Group III nitride semiconductor according to claim 4, wherein a concentration of the P-type dopant in the melt is 0.1 mol% or more.

14. The method for producing a Group III nitride semiconductor according to claim 1, wherein a concentration of the P-type dopant in the Group III nitride semiconductor is 10⁸ cm⁻³ or more.

15. The method for producing a Group III nitride semiconductor according to claim 2, wherein a concentration of the P-type dopant in the Group III nitride semiconductor is 10⁸ cm⁻³ or more.

16. The method for producing a Group III nitride semiconductor according to claim 3, wherein a concentration of the P-type dopant in the Group III nitride semiconductor is 10⁸ cm⁻³ or more.

17. The method for producing a Group III nitride semiconductor according to claim 4, wherein a concentration of the P-type dopant in the Group III nitride semiconductor is 10⁸ cm⁻³ or more.

18. The method for producing a Group III nitride semiconductor according to claim 1, wherein a concentration of Ca in the melt is less than 0.01 mol%.

19. The method for producing a Group III nitride semiconductor according to claim 2, wherein a concentration of Ca in the melt is less than 0.01 mol%.

20. The method for producing a Group III nitride semiconductor according to claim 3, wherein a concentration of Ca in the melt is less than 0.01 mol%.
